(19) United States
(12) Patent Application Publication
(10) Pub. No.: US 2023/0106132 A1
(43) Pub. Date: Apr. 6, 2023

(54) Cleaning Composition for Post Chemical Mechanical Planarization And Method Of Using The Same

(71) Applicant: Ferro Corporation, Mayfield Heights, OH (US)

(72) Inventors: Yihan YANG, Zhongli City (TW); Cheyu KUO, Zhongli City (TW); Chengchun HUANG, Zhongli City (TW); Hoying WU, Zhongli City (TW); Mingche HO, Zhongli City (TW); Minghui LU, Zhongli City (TW)

(21) Appl. No.: 17/802,657

(22) PCT Filed: Mar. 18, 2021
(86) PCT No.: PCT/IB2021/000147

§ 371 Date: Aug. 26, 2022

Related U.S. Application Data
(60) Provisional application No. 62/991,120, filed on Mar. 18, 2020.

(51) Int. Cl. C11D 7/32; C11D 7/50; C11D 7/26; C11D 7/06; C11D 11/00; H01L 21/02

(52) U.S. Cl. CPC C11D 7/3245; C11D 7/06; C11D 7/261; C11D 7/265; C11D 7/267; C11D 7/3281; C11D 7/5022; C11D 11/0047; H01L 21/02074

(57) ABSTRACT

The present invention provides a cleaning composition for post CMP cleaning and method for post CMP cleaning microelectronic device. The cleaning composition according to the invention includes at least one chelating agent, at least one organic solvent, at least one polycarboxylic acid, at least one basic pH adjustor, at least one metal anticorrosive agent, and water. The TMAH-free cleaning composition according to the invention provides improved cleaning efficiency and electrochemical compatibility with both cobalt and copper materials.

### BACKGROUND OF THE INVENTION

### Field of Invention

The present invention relates to a cleaning composition and method for post chemical mechanical planarization (CMP) cleaning. In particular, the present invention relates to a cleaning composition for post-CMP cleaning while substantially inhibiting corrosion of copper and/or cobalt.

### Brief Description of Related Art

A variety of cleaning compositions are required in chemical mechanical planarization (CMP) process to remove contaminants at various steps in microelectronics device fabrication. Most of contaminants are located on the surface of the microelectronic device. Therefore, it is critical to remove contaminants after CMP process to improve process yield at each fabrication stage, which is referred to as post CMP cleaning.

A particular importance in improved post CMP cleaning exists in copper (Cu) interconnects, which connects active devices on a substrate of a microelectronic device. After the copper is deposited, a semiconductor substrate such as wafer may be polished by a CMP process using a variety of abrasives such as alumina, zirconia, silica, titania and ceria. The CMP process removes an excess copper deposits and planarizes the surface for the subsequent photolithographic steps. After the CMP process, a surface of the substrate includes a large number of contaminants. After the CMP process, the microelectronic device can be cleaned using a cleaning composition for post CMP cleaning by dispersing a cleaning composition on the surface of the microelectronic device. The cleaning composition can be removed by rinsing with deionized water, followed by a drying process.

The foregoing and other features of the invention are hereafter more fully described and particularly pointed out in the claims, the following description setting forth in detail certain illustrative embodiments of the invention, these being indicative, however, of but a few of the various ways in which the principles of the present invention may be employed.

### BRIEF SUMMARY OF THE INVENTION

The present invention provides a cleaning composition for a post chemical mechanical planarization (CMP) cleaning at various steps of a microelectronic device fabrication. The cleaning composition of the invention removes contaminants generated on a surface of a microelectronic device during a CMP polishing, while effectively reducing the corrosion of cobalt (Co) and/or copper (Cu) than can be achieved with conventional cleaning compositions. A cleaning composition according to the invention comprises at least one chelating agent, at least one organic solvent, at least one polycarboxylic acid, at least one basic pH adjustor, at least one metal anticorrosive agent, and water.

An embodiment of the invention is cleaning composition including a chelating agent. The chelating agent can include, but not limited to mono and/or polyalkylene polyamino polycarboxylic acids, polyaminoalkane polycarboxylic acids, and combinations thereof. Representative but non-limiting examples further include ethylenediaminetetraacetic acid (EDTA), diethylenetriaminepentaacetic acid (DTPA), ethylenediaminetetra-n-propionic acid (EDTPA), triethylenetetramine hexaacetic acid (TTHA), diaminopropanoltetraacetic acid (DHTPA), 1,3-propylenediaminetertaacetic acid (PDTA), glycine, and iminodiacetic acid (IDA), and derivatives thereof, and combinations thereof.

An embodiment of the invention is a cleaning composition including at least one organic solvent selected from water-soluble alcohol groups, ketone groups, ester groups, ether groups, and derivatives thereof, and combination thereof.

An embodiment of the invention is a cleaning composition including at least one polycarboxylic acid. The at least one polycarboxylic acid can include, but is not limited to, straight- and/or branch-chained, saturated and/or unsaturated, aromatic polycarboxylic acids containing 2-20 carbon atoms, and derivatives thereof, and combinations thereof. Representative but non-limiting examples further include oxalic acid, malonic acid, tricarballylic acid, ascorbic acid, citric acid, succinic acid, butanedioic acid, pentanedioic aicd, malic acid, tartaric acid, tannic acid, adipic acid, and derivatives thereof, and combinations thereof.

An embodiment of the invention is a cleaning composition including at least one basic pH adjustor. The basic pH adjustor can include, but not limited to, tetraethylammonium hydroxide (TEAH), tetramethylammonium hydroxide (TMAH), tetrapropylammonium hydroxide (TPAH), tetrabutylammonium hydroxide (TBAH), tributylmethylammonium hydroxide (TBMAH), benzyltrimethylammonium hydroxide (BTMAH), ethyltriethyl ammonium hydroxide (ETAH), methyl(trishydroxyethyl)ammonium hydroxide, tetrabutylphosphonium hydroxide (TBPH), ethyltrimethylammonium hydroxide (ETMAH), sodium hydroxide, potassium hydroxide, sodium carbonate, potassium carbonate, and derivatives thereof, and combinations thereof. As will be evident from a review of at least this paragraph, “basic pH adjustor” is an additive that raises the pH of the solution to which it is added or in which it is included.

Another embodiment of the invention is a cleaning composition including at least one basic pH adjustor, the basic pH adjustor being free of TMAH, BTMAH, or ETMAH. Instead, the basic pH adjustor can include TEAH, TPAH, TBAH, BTMAH, ETAH, methyl(trishydroxyethyl)ammonium hydroxide, TBPH, sodium hydroxide, potassium hydroxide, sodium carbonate, potassium carbonate, and derivatives thereof, and combinations thereof.

An embodiment of the invention is a cleaning composition including at least one metal anticorrosive agent. The metal anticorrosive agent can include, but is not limited to, benzotriazole (BTA), 1 H-1,2,4-triazole (TAZ), 5-nitrobenzotriazole, indazole, resorcin, pyruvate, amino acids, adenine, adenosine, guanosine, glycine, iminodiacetic acid, ascorbic acid, ascorbic acid derivatives, citric acid, citric acid derivatives, uric acid, uric acid derivatives, and combinations thereof.

An embodiment of the invention is a method of removing contaminants from a microelectronic device. The method comprises cleaning a surface of the microelectronic device by contacting the surface to be cleaned with a cleaning composition. The cleaning composition comprises at least one chelating agent in an amount ranging from 0 to about 5 wt.%, at least one organic solvent in an amount ranging from about 0.1 to about 25 wt.%, at least one polycarboxylic acid in an amount ranging from 0.01 to about 5 wt.%, at least one basic pH adjustor in an amount ranging from about 1 to about 20 wt.%, at least one metal anticorrosive agent in an amount ranging from about 0.01 to about 6 wt.%, and water in an amount ranging from 39 to about 98 wt.%.

An embodiment of the invention is a microelectronic device comprising a substrate, a copper layer, and a cobalt layer. The microelectronic device includes contaminants on the surface of the copper layer and the cobalt layer. The contaminants are removed by cleaning a surface of the microelectronic device by contacting the surface to be cleaned with a cleaning composition. The cleaning composition comprises at least one chelating agent in an amount ranging from to about 5 wt.%, at least one organic solvent in an amount ranging from about 0.1 to about 25 wt.%, at least one polycarboxylic acid in an amount ranging from 0.01 to about 5 wt.%, at least one basic pH adjustor in an amount ranging from about to about 20 wt.%, at least one metal anticorrosive agent in an amount ranging from about 0.01 to about 6 wt.%, and water in an amount ranging from to about 98 wt.%.

The foregoing and other features of the invention are hereinafter more fully described and particularly pointed out in the claims, the following description setting forth in detail certain illustrative embodiments of the invention, these being indicative, however, of but a few of the various ways in which the principles of the present invention may be employed.

### DETAILED DESCRIPTION OF THE INVENTION

The present invention is a cleaning composition, in particular, a post chemical mechanical planarization (CMP) cleaning composition for removing contaminants generated from a CMP process during fabrication of a microelectronic device. During the post CMP cleaning process with cleaning composition according to the invention, galvanic corrosion of copper (Cu) and/or cobalt (Co) circuits formed on the microelectronic device needs to be reduced to prevent, for example, side slits between Cu and Co stack. The cleaning composition according to the invention further provides improved cleaning efficacy during post CMP cleaning, enabling the improvement of process yield. The cleaning composition comprises at least one chelating agent, at least one organic solvent, at least one polycarboxylic acid, at least one basic pH adjustor, at least one metal anticorrosive agent, and water. The cleaning composition may be prepared to be alkaline in nature.

Throughout the specification and in the claims, the phrase “microelectronic device” refers to semiconductor substrates, flat panel displays, solar panels and other products including solar substrates, photovoltaics, and microelectromechanical system (MEMS), As used herein, “contaminants” refer to inorganic particles, inorganic / organic residues, chemical residues, metal ions, any reaction products on the surface of the microelectronic device due to interaction of the microelectronic device with CMP slurry compositions and elevated levels of undesirable metals on the surface. The contaminants can further include any reaction products generated from CMP process, the wet etching, the plasma etching or the plasma ashing process.

The CMP polishing process can leave contaminants on the surface of the microelectronic device after the completion of the CMP polishing. The contaminants need to be removed prior to subsequent processing of the microelectronic device in order to avoid degradation in the device reliability and to avoid the introduction of defects that are responsible for reducing the manufacturing yield. The defects can include particles or scratches. For this defect free surface, the microelectronic device is cleaned using a brush scrubbing process, during which a post CMP cleaning composition can be dispensed on the surface of the microelectronic device to remove the contaminants.

Copper (Cu) is a material of choice in the production of interconnects in the fabrication of the microelectronic devices. Cu interconnects include metallic interconnects that are predominantly copper or a copper alloy. It is understood that the surface of the microelectronic device includes semiconductor materials including but not limited to TiN, Ta, TiW, TaN acting as copper diffusion barrier metals. The Cu interconnects can also include Ta/TaN bilayer. The Cu interconnects with Ta/TaN bilayer can have difficulty in achieving Cu gap fill and in preventing electromigration.

Cobalt (Co) can be used as contact plugs and interconnects. Further, Co can be integrated to Cu interconnects to replace Ta in Ta/TaN bilayer. Co also has advantages of lower resistivity, better step coverage and wettability than Ta layer. Co also have advantage of enabling direct electroplating of Cu without a seed layer. On the other hand, corrosion can be observed during CMP polishing and following cleaning process. Further, the galvanic corrosion of Cu and Co during CMP polishing can be problematic. The standard equilibrium electrical potential for Cu²⁺/Cu and Co²⁺/Co are +0.34 V and -0.28 V, respectively. The potential difference can cause galvanic corrosion with Co acting as the anode at the Cu/Co interface.

Cleaning compositions according to the invention can be used to remove contaminants on the surface of the microelectronic device following a CMP process, but are also suitable for reducing the corrosion of Cu-Co interconnects in the microelectronic devices. As shown in the accompanying Examples, cleaning compositions according to the invention provide substantially small corrosion potential difference between cobalt and copper (ΔE_{Co-Cu}), reduced cobalt corrosion current, and reduced cobalt corrosion rate. Therefore, cleaning compositions according to the invention provide reduced galvanic corrosion situation by the cobalt post CMP cleaning process, and does not provide any source for device degradation resulting from the corrosion of Cu and/or Co. Furthermore, cleaning compositions according to the invention provide reduced number of defects after post CMP cleaning process, which would be advantageous in improving process yield in each step in the microelectronic device fabrication.

An advantage of the invention is cleaning compositions that are free of tetramethylammonium hydroxide (TMAH). CMP slurries typically include TMAH. Further, TMAH-free compositions can prevent unexpected attack on the substrate from the relatively high static etch rate of TMAH, which can result in additional recesses in the substrate. For similar reasons, the cleaning compositions described herein can also be free of benzyltrimethylammonium hydroxide (BTMAH) and ethyltrimethylammonium hydroxide (ETMAH).

Cleaning compositions according to the present invention comprise at least one chelating agent, at least one organic solvent, at least one polycarboxylic acid, at least one basic pH adjustor, at least one metal anticorrosive agent, and water. In one embodiment, the basic pH adjustor of the cleaning compositions described herein can include at least one of tetraethylammonium hydroxide (TEAH), TMAH, tetrapropylammonium hydroxide (TPAH), tetrabutylammonium hydroxide (TBAH), tributylmethylammonium hydroxide (TBMAH), BTMAH, ethyltriethyl ammonium hydroxide (ETAH), methyl(trishydroxyethyl)ammonium hydroxide, tetrabutylphosphonium hydroxide (TBPH), ETMAH, sodium hydroxide, potassium hydroxide, sodium carbonate, potassium carbonate, and derivatives thereof, and combinations thereof.

In another embodiment, cleaning compositions according to the present invention can include at least one basic pH adjustor, and the basic pH adjustor can be free of TMAH, BTMAH, or ETMAH. For example, the cleaning compositions according to the present invention can be TMAH free, BTMAH free, or ETMAH free. Instead, the basic pH adjustor of the cleaning compositions described herein can include at least one of TEAH, TPAH, TBAH, BTMAH, ETAH, methyl(trishydroxyethyl)ammonium hydroxide, TBPH, sodium hydroxide, potassium hydroxide, sodium carbonate, potassium carbonate, and derivatives thereof, and combinations thereof.

As defined herein, a chelating agent can chemically combine with or physically hold the metal ion contaminants on the device surface and dissolve them into the cleaning composition according to the invention. Further, the chelating agent can scavenge these metal ions in the cleaning composition, and prevent the ions from redepositing on the surface of the device. The chelating agent can include mono and/or polyalkylene polyamino polycarboxylic acids, polyaminoalkane polycarboxylic acids, and combinations thereof. The chelating agent can further include, but not limited to, ethylenediaminetetraacetic acid (EDTA), diethylenetriaminepentaacetic acid (DTPA), ethylenediaminetetra-n-propionic acid (EDTPA), triethylenetetramine hexaacetic acid (TTHA), diaminopropanoltetraacetic acid (DHTPA), 1,3-propylenediaminetertaacetic acid (PDTA), glycine, and iminodiacetic acid (IDA), and combinations thereof. In another embodiment, more than one chelating agent can be combined in the cleaning composition.

The cleaning composition comprises at least one polycarboxylic acid. Polycarboxylic acid may be effective in removing contaminants such as micro-sized particles and metal impurities from the surface of the microelectronic device without corroding the copper interconnects. Suitable polycarboxylic acids can be selected from straight and/or branch chains, saturated and/or unsaturated, 2-20 carbon atom containing aromatic polycarboxylic acids, and derivatives thereof, and combinations thereof. For example, suitable polycarboxylic acids include oxalic acid, malonic acid, tricarballylic acid, ascorbic acid, citric acid, succinic acid, butanedioic acid, pentanedioic acid, malic acid, tartaric acid, tannic acid, adipic acid, and derivatives of the foregoing thereof, and combinations of the foregoing.

The cleaning composition comprises at least one metal anticorrosive agent. The metal anticorrosive agent inhibits or prevents the corrosion or oxidation of copper and/or other metals. For example, the metal anticorrosive agent is added to the cleaning composition to lower the corrosion rate of metal, for example, copper, and cobalt, as well as enhance the cleaning performance. Examples of the metal anticorrosive agent according to the present invention can include, but not limited to, benzotriazole (BTA), 1 H-1,2,4-triazole (TAZ), 5-nitrobenzotriazole, indazole, resorcin, pyruvate, amino acids, adenine, adenosine, guanosine, glycine, iminodiacetic acid, ascorbic acid, ascorbic acid derivatives, citric acid, citric acid derivatives, uric acid, uric acid derivatives, and combinations thereof.

One or more metal anticorrosive agents can be used according to the present invention. For example, the cleaning composition can include benzotriazole (BTA) and ascorbic acid (AA) to act as metal anticorrosive agent. The relative amount of benzotriazole (BTA) and ascorbic acid (AA) can be adjusted to be substantially same, 1:1. The relative amount of BTA and AA can also be adjusted to 0:1 or 1:0 as shown in Table 1 herein.

The cleaning composition according to the invention is suitable for removing contaminants, for example, from post-CMP, post-etch, post-ash, and contaminants from a semiconductor device.

The cleaning compositions according to the present invention can be prepared by mixing or combining at least one chelating agent, at least one organic solvent, at least one polycarboxylic acid, at least one basic pH adjustor and at least one metal anticorrosive agent in deionized water in a suitable manner so as to form a generally homogeneous mixture of the components in the cleaning composition. The cleaning composition is further prepared such that the pH of the cleaning composition is controlled.

For example, the pH of the cleaning composition can be varied to produce a composition suited the intended use. In general, the pH can be basic, for example, greater than 7, or greater than 7 and less than 14. In one embodiment, the pH of the cleaning composition is adjusted to be within the range of from about 10 to about 14. In another embodiment, the pH of the cleaning composition is adjusted to be within the range of about 11 to about 13. In still another embodiment, the pH of the cleaning composition is adjusted to be within the range of about 11.5 to about 12.5. In yet still another embodiment, the pH of the cleaning composition is about 12.

The cleaning composition according to the present invention is preferably aqueous, meaning that the individual components of the cleaning are dispersed in water. The water can be preferably deionized water. However, other liquid can be also used.

In one embodiment, cleaning compositions according to the invention include at least one chelating agent; at least one organic solvent; at least one polycarboxylic acid; at least one basic pH adjustor; at least one metal anticorrosive agent, and; water. The basic pH adjustor of the cleaning composition is selected from the group consisting of TEAH, TMAH, TPAH, TBAH, TBMAH, BTMAH, ETAH, methyl(trishydroxyethyl)ammonium hydroxide, TBPH, ETMAH, sodium hydroxide, potassium hydroxide, sodium carbonate, potassium carbonate, and derivatives thereof, and combinations thereof. In another embodiment, the basic pH adjustor can be free of TMAH, BTMAH, or ETMAH; and can be selected from the group consisting of TEAH, TPAH, TBAH, TBMAH, ETAH, methyl(trishydroxyethyl)ammonium hydroxide, TBPH, sodium hydroxide, potassium hydroxide, sodium carbonate, potassium carbonate, and derivatives thereof, and combinations thereof.

In one embodiment, cleaning composition according to the invention includes at least one chelating agent in an amount ranging from 0 to about 5 wt%; at least one organic solvent in an amount ranging from about 0.1 to about 25 wt%; at least one polycarboxylic acid in an amount ranging from 0.01 to about 5 wt%; at least one basic pH adjustor in an amount ranging from about 1 to about 20 wt%; at least one metal anticorrosive agent in an amount ranging from about 0.01 to about 6 wt%; and water in an amount ranging from 39 to about 98 wt%.

In one embodiment, cleaning composition according to the invention includes at least one chelating agent in an amount ranging from 0.01 to about 3 wt%; at least one organic solvent in an amount ranging from about 0.5 to about 20 wt%; at least one polycarboxylic acid in an amount ranging from 0.01 to about 4 wt%; at least one basic pH adjustor in an amount ranging from about 1.5 to about 20 wt%; at least one metal anticorrosive agent in an amount ranging from about 0.01 to about 4 wt%; and water in an amount ranging from 49 to about 97 wt%.

In one embodiment, cleaning composition according to the invention includes at least one chelating agent in an amount ranging from 0.01 to about 2 wt%; at least one organic solvent in an amount ranging from about 2 to about 17 wt%; at least one polycarboxylic acid in an amount ranging from 0.01 to about 3 wt%; at least one basic pH adjustor in an amount ranging from about 2 to about 20 wt%; at least one metal anticorrosive agent in an amount ranging from about 0.01 to about 3 wt%; and water in an amount ranging from 55 to about 95 wt%.

In one embodiment, cleaning composition according to the invention includes at least one chelating agent in an amount ranging from 0.01 to about 1.5 wt%; at least one organic solvent in an amount ranging from about 3 to about 15 wt%; at least one polycarboxylic acid in an amount ranging from 0.01 to about 3 wt%; at least one basic pH adjustor in an amount ranging from about 4 to about 15 wt%; at least one metal anticorrosive agent in an amount ranging from about 0.01 to about 2.5 wt%; and water in an amount ranging from 63 to about 92 wt%.

In one embodiment, cleaning composition according to the invention includes at least one chelating agent in an amount ranging from 0.5 to about 1.5 wt%; at least one organic solvent in an amount ranging from about 7 to about 12 wt%; at least one polycarboxylic acid in an amount ranging from 0.01 to about 2.5 wt%; at least one basic pH adjustor in an amount ranging from about 7 to about 11 wt%; at least one metal anticorrosive agent in an amount ranging from about 0.5 to about 2.5 wt%; and water in an amount ranging from 70.5 to about 85 wt%.

It will be appreciated that surfactants, biocides, pH buffers, rheology modifiers and other additives can also be present in the cleaning composition provided they do not adversely affect the cleaning efficiency of the cleaning compositions, or do not detrimentally affect the final surface quality produced via polishing.

The cleaning composition according to the invention can be provided to a post CMP cleaning process to at least partially remove contaminants on the microelectronic device. An appropriate amount of the cleaning composition can be contacted with the surface of the microelectronic device for a time of from about 10 seconds to about 3 minutes, preferably from about 20 seconds to about 2 minutes, and more preferably from about 30 seconds to about 1 minute at a temperature ranging from about 10° C. to about 50° C., preferably from about 15° C. to about 40° C., more preferably from 20° C. to about 30° C. It is noted that the above contacting time and temperature are merely illustrative, and any other suitable time and temperature range can be used to remove at least contaminants from the microelectronic device.

Following the cleaning step, the cleaning composition is removed from the surface of the microelectronic device. Any rinse solution can be applied as necessary to the surface of the microelectronic device. The rinse solution can include deionized water. Thereafter, the microelectronic device can be further dried using a spin dryer.

The post CMP cleaning process can be incorporated into the fabrication process of a microelectronic device. The post CMP cleaning composition according to the invention can be provided to remove contaminants in the fabrication process including but not limited to post CMP cleaning, post etch contaminants removal, post ash contaminants removal, post plating cleaning, photoresist removal, various applications in back-end packaging such as wafer cleaning, dicing, grinding etc. The post CMP cleaning composition can be provided to the device according to a method according to the invention. The device can include a substrate on which copper interconnects including copper layer can be formed. The device further can include cobalt layer as barrier layer. In one embodiment, copper interconnects can include both copper layer and cobalt layer in direct contact with each other.

The following examples are intended only to illustrate the invention and should not be construed as imposing limitations upon the claims.

### EXAMPLES

In the following examples, cleaning compositions according to the invention can effectively reduce the electrochemical corrosion between copper and cobalt. The cleaning compositions further provide post-CMP cleaning that effectively removes contaminants on the surface of the microelectronic device.

Cleaning compositions 1-6 were each made individually by mixing together the amounts of the components shown in weight percent in Table 1 below. Individual components are dispersed in water to form a 100 wt% cleaning composition. Cleaning compositions in Table 1 were tested for electrochemical properties and defect measurement. Cleaning compositions 1-6 include predetermined amounts of EDTA (chelating agent), Ethylene Glycol (organic solvent), Butanedioic acid (polycarboxylic acid), KOH (basic pH adjustor), BTA (metal anticorrosive agent), Ascorbic acid (metal anticorrosive agent) as shown in Table 1. Some cleaning compositions did not include one or more components described above. For example, cleaning composition 5 did not include butanedioic acid, and cleaning composition 6 did not include chelating agent (EDTA). One or more metal anticorrosive agents were selectively used in cleaning compositions 1-6. Cleaning composition 1 did not include metal anticorrosive agent. Cleaning compositions 4-6 included two anticorrosive agents. The pH of all cleaning compositions was adjusted in the alkali range at about 12.

TABLE 1

| Composition No. | Composition (by wt.%) | | | | | | pH value |
|---|---|---|---|---|---|---|---|
| | EDTA | Ethylene Glycol | Butanedioic Acid | KOH | Benzotriazole (BTA) | Ascorbic Acid | |
| 1 | 1 | 10 | 2 | 10 | 0 | 0 | 12 |
| 2 | 1 | 10 | 2 | 10 | 1 | 0 | 12 |
| 3 | 1 | 10 | 2 | 10 | 0 | 1 | 12 |
| 4 | 1 | 10 | 2 | 10 | 1 | 1 | 12 |
| 5 | 1 | 10 | 0 | 10 | 1 | 1 | 12 |
| 6 | 0 | 10 | 2 | 10 | 1 | 1 | 12 |

Electrochemical Analysis. The potentiodynamic polarization curve measurements of copper and cobalt layers were conducted using a potentiostat (Electrochemistry REFERENCE 600™, GARMY Instruments, USA) to determine the efficiency of cleaning compositions 1-6 on the corrosion behavior of different layers by 200 mm blanket copper and cobalt wafers, which are typically prepared by the physical vapor deposition of cobalt and electrochemical plating copper processes. The thickness of copper and cobalt blanket layers were approximately 1.5 and 0.2 micron, respectively. As-deposited Cu and Co samples were cleaned using cleaning compositions according to the invention 1-6 shown in Table 1. Cleaning compositions were provided to copper and cobalt samples. Each of cleaning compositions were contacted with the Cu and Co samples for 5 minutes at a room temperature of 25° C. while the microelectronic device is cleaned using a brush scrubbing process. After the device is cleaned, the device is rinsed with deionized water, followed by spin drying to remove all contaminants and deionized water.

For measurements, calomel material was used as reference electrode, and carbon material was used as auxiliary electrode. The dynamic potential polarization curves were obtained at a scanning rate of 10 mV/sec. Corrosion potential (Ecorr), corrosion current (Icorr), corrosion rate of copper and cobalt were measured. In addition, the corrosion potential difference of copper and cobalt (ΔE_{Co-Cu}) was also calculated and shown in Table 2 below.

It is noted that the efficacy of the cleaning compositions 1-6 was dependent upon the relative amounts of constituents within each cleaning compositions. After cleaning the samples using cleaning composition 1, the absolute value of corrosion potential difference of copper and cobalt was found to be relatively high (ΔE_{Co-Cu} of -220 mV) compared to other cleaning compositions tested herein. Cleaning compositions 3 and 4 showed smaller corrosion potential differences of copper and cobalt (ΔE_{Co-Cu} of 9 mV for cleaning composition 3, ΔE_{Co-Cu} of 6 mV for cleaning composition 4) compared to other cleaning compositions, and showed best results of the cleaning compositions tested herein. Cleaning compositions 5 and 6 also showed promising results for corrosion potential differences (ΔE_{Co-Cu}) of -9 mV (for cleaning composition 5) and -10 mV (for cleaning composition 6).

Corrosion current and corrosion rate for copper and cobalt were also determined to be smaller for cleaning compositions 3 and 4 compared to other cleaning compositions. For example, corrosion current of copper and cobalt in cleaning compositions 3 and 4 were 12 and 7 µA (for cleaning composition 3) and 16 and 9 µA (for cleaning composition 4), respectively. Corrosion current of copper and cobalt in cleaning compositions 3 and 4 were 0.041 and 0.020 millimeters per year (mmpy) (for cleaning composition 3), and 0.053 and 0.028 mmpy (for cleaning composition 4), respectively. On the other hand, corrosion current and corrosion rate for compositions 5 and 6 were found to be higher by at least one order of magnitude, when compared to cleaning compositions 3 and 4.

TABLE 2

| Composition No. | Corrosion Potential (mV) | | | Corrosion Current (µA) | | Corrosion Rate (mmpy) | |
|---|---|---|---|---|---|---|---|
| | Cu | Co | ΔE_{Co-Cu} | Cu | Co | Cu | Co |
| 1 | -322 | -542 | -220 | 3 | 42 | 0.009 | 0.130 |
| 2 | -410 | -480 | -70 | 18 | 10 | 0.058 | 0.032 |
| 3 | -436 | -427 | 9 | 12 | 7 | 0.041 | 0.020 |
| 4 | -409 | -403 | 6 | 16 | 9 | 0.053 | 0.028 |
| 5 | -301 | -310 | -9 | 47 | 37 | 0.155 | 0.113 |
| 6 | -312 | -322 | -10 | 33 | 25 | 0.104 | 0.81 |

Defect Test. The efficacy of the cleaning compositions according to the invention was also evaluated by comparing the defect counts before and after post CMP cleaning. For this test, blanket copper and cobalt layered samples are prepared on different layers by 200 mm blanket copper and cobalt wafers, which are typically prepared by the physical vapor deposition of cobalt and electrochemical plating copper processes. Subsequently, all of the blanket copper and cobalt samples are CMP polished on Mirra® CMP system (for 8-inch, 200 mm wafer polishing, AMAT). CMP slurry including colloidal silica-based abrasive particles were used for polishing devices with blanket copper and blanket cobalt layers. CMP polishing conditions are as follows: under 1.5 psi down force and suitable controlled head/pad rotation speeds by polishing for 1 minute at room temperature of 25° C. While colloidal silica-based abrasive particles are used for polishing prior to post CMP cleaning process, it is noted that other CMP slurries including other abrasive particles can also be used in combination with the post CMP cleaning compositions according to the present invention. After CMP polishing, cleaning compositions according to the invention were provided to an OnTrak DSS-200 cleaning system (Lam Research, Fremont, CA, USA) for post CMP cleaning. In one example, the CMP polishing process for copper may include multiple steps such as initial copper planarization, copper cleaning step, and barrier metal cleaning. Cleaning compositions 1 and 4 were tested for the purpose of evaluating cleaning efficacy of cleaning compositions. The post CMP cleaning conditions are as follows: An alkaline post CMP cleaning composition is introduced and sprayed on the polished surfaces of copper and cobalt layers for one (1) minute and deionized water is provided for removing the diluted alkaline post CMP cleaning composition. The post CMP cleaning compositions can be diluted with an appropriate liquid with a dilution ratio in the range of about 1:20 to 1:100, preferably about 1:30 to 1:80, more preferably about 1:40to 1:60, most preferably about 1:45 to 1:55. The liquid may include DI water.

After post CMP cleaning, the surface of the blanket copper and cobalt layers on a microelectronic device are analyzed to measure the number and distribution of defect particles using a defect check system (Surfscan™ SP1 TBI, KLA-Tencor Corp, Milpitas, CA, USA). Defect counts for the blanket copper and blanket cobalt layers were collected and normalized results are shown in Table 3 below.

Table 3 shows the defect counts (normalized) for blanket Cu and blanket Co after post CMP cleaning. Defect counts for a predetermined area of Cu and Co area are determined by the defect check system, and then normalized to demonstrate the impact of the cleaning composition on the number of remaining defects on the surface of blanket Cu and blanket Co. It is noted that the cleaning composition 4 showed substantially reduced defect counts on both copper and cobalt layers compared to the cleaning composition 1. For blanket copper layers, post CMP cleaning process was conducted under identical cleaning conditions for cleaning compositions 1 and 4. After post CMP cleaning process, it was found that the cleaning composition 4 reduced the defects by 72% more, compared to the cleaning composition 1. Similarly, cleaning cobalt layer with cleaning composition 4 was more effective in removing the contaminants than using cleaning composition 1. Cleaning composition 4 reduced the defects by 63% more, compared to using cleaning composition 1. Table 3 further confirms that cleaning composition 4 shows better results in removing contaminants formed on the surface of the microelectronic device to have less number of defects than cleaning composition 1, as well as in substantially reducing galvanic corrosion of Cu and Co to prevent the formation of side slits between Cu and Co as shown in Table 2.

TABLE 3

| Composition No. | Defect Counts (normalized) | |
|---|---|---|
| | Blanket Cu | Blanket Co |
| 1 | 1.00 | 1.00 |
| 4 | 0.28 | 0.37 |

It is noted that the method of determining the defect counts is provided for example only and is not intended to be limited to same. For example, atomic force microscopy (AFM) may be programmed to perform a z-plane scan to identify topographic area of interest above a certain height threshold and then calculate the area of the total surface covered by the areas of interest. A skilled artisan would readily understand that the less area covered by the areas of interest post-cleaning, the more effective the post CMP cleaning composition.

The cleaning composition for post CMP cleaning according to the invention has advantages over conventional cleaning composition in that the cleaning compositions significantly reduce a galvanic corrosion of Cu and Co, which can be beneficial in a Cu interconnects on the surface of the microelectronic device. Further, the cleaning composition for post CMP cleaning according to the invention can improve post cleaning efficiency by having reduced number of defects measured after post CMP cleaning compared to other cleaning compositions.

In conclusion, proposed formulated post CMP cleaning compositions are enclosing for better clean performance on copper and cobalt surfaces by the defect checking, and the relative small corrosion potential difference of cobalt and copper and low corrosion rate for copper and cobalt can be investigated by the electrochemical analysis test.

Additional advantages and modifications will readily occur to those skilled in the art. Therefore, the invention in its broader aspects is not limited to the specific details and illustrative examples shown and described herein. Accordingly, various modifications may be made without departing from the spirit or scope of the general inventive concept as defined by the appended claims and their equivalents.

The invention is further defined by the following items.

Item 1. A cleaning composition for removing contaminants from a microelectronic device, the composition comprising:
at least one chelating agent;
at least one organic solvent;
at least one polycarboxylic acid;
at least one basic pH adjustor;
at least one metal anticorrosive agent; and water.

Item 2. The cleaning composition of item 1, wherein the composition comprises:
at least one chelating agent in an amount ranging from 0 to about 5 wt.%;
at least one organic solvent in an amount ranging from about 0.1 to about 25 wt.%;
at least one polycarboxylic acid in an amount ranging from 0.01 to about 5 wt.%;
at least one basic pH adjustor in an amount ranging from about 1 to about 20 wt.%;
at least one metal anticorrosive agent in an amount ranging from about 0.01 to about 6 wt.%; and
water in an amount ranging from 39 to about 98 wt.%.

Item 3. The cleaning composition of item 1, wherein the composition comprises:
at least one chelating agent in an amount ranging from about 0.01 to about 3 wt.%;
at least one organic solvent in an amount ranging from about 0.5 to about 20 wt.%;
at least one polycarboxylic acid in an amount ranging from 0.01 to about 4 wt.%;
at least one basic pH adjustor in an amount ranging from about 1.5 to about 20 wt.%;
at least one metal anticorrosive agent in an amount ranging from about 0.01 to about 4 wt.%; and
water in an amount ranging from 49 to about 97 wt.%.

Item 4. The cleaning composition of item 1, wherein the composition comprises:
at least one chelating agent in an amount ranging from about 0.01 to about 2 wt.%;
at least one organic solvent in an amount ranging from about 2 to about 17 wt.%;
at least one polycarboxylic acid in an amount ranging from 0.01 to about 3 wt.%;
at least one basic pH adjustor in an amount ranging from about 2 to about 20 wt.%;
at least one metal anticorrosive agent in an amount ranging from about 0.01 to about 3 wt.%; and
water in an amount ranging from 55 to about 95 wt.%.

Item 5. The cleaning composition of item 1, wherein the composition comprises:
at least one chelating agent in an amount ranging from about 0.01 to about 1.5 wt.%;
at least one organic solvent in an amount ranging from about 3 to about 15 wt.%;
at least one polycarboxylic acid in an amount ranging from 0.01 to about 3 wt.%;
at least one basic pH adjustor in an amount ranging from about 4 to about 15 wt.%;
at least one metal anticorrosive agent in an amount ranging from about 0.01 to about 2.5 wt.%; and
water in an amount ranging from 63 to about 92 wt.%.

Item 6. The cleaning composition of item 1, wherein the composition comprises:
at least one chelating agent in an amount ranging from about 0.5 to about 1.5 wt.%;
at least one organic solvent in an amount ranging from about 7 to about 12 wt.%;
at least one polycarboxylic acid in an amount ranging from 0.01 to about 2.5 wt.%;
at least one basic pH adjustor in an amount ranging from about 7 to about 11 wt.%;
at least one metal anticorrosive agent in an amount ranging from about 0.5 to about 2.5 wt.%; and
water in an amount ranging from 70.5 to about 85 wt.%.

Item 7. The cleaning composition of item 1, wherein the composition has a pH ranging from 10 to 14.

Item 8. The cleaning composition of item 7, wherein the pH ranges from 11 to 13.

Item 9. The cleaning composition of item 1, wherein the at least one chelating agent comprises one or more species selected from the group consisting of mono and/or polyalkylene polyamino polycarboxylic acids, polyaminoalkane polycarboxylic acids, and derivatives thereof, and combinations thereof.

Item 10. The cleaning composition of item 1, wherein the at least one chelating agent comprises one or more species selected from the group consisting of ethylenediaminetetraacetic acid (EDTA), diethylenetriaminepentaacetic acid (DTPA), ethylenediaminetetra-n-propionic acid (EDTPA), triethylenetetramine hexaacetic acid (TTHA), diaminopropanoltetraacetic acid (DHTPA), 1,3-propylenediaminetertaacetic acid (PDTA), glycine, and iminodiacetic acid (IDA), and derivatives thereof, and combinations thereof.

Item 11. The cleaning composition of item 1, wherein the organic solvent comprises one or more species selected from the group consisting of water-soluble alcohol groups, ketone groups, ester groups, ether groups, and derivatives thereof, and combinations thereof.

Item 12. The cleaning composition of item 1, wherein the at least one polycarboxylic acid comprises one or more species selected from the group consisting of straight and/or branch chains, saturated and/or unsaturated, 2-20 carbon atom containing aromatic polycarboxylic acids, and derivatives thereof, and combinations thereof.

Item 13. The cleaning composition of item 1, wherein the polycarboxylic acid comprises one or more species selected from the group consisting of oxalic acid, malonic acid, tricarballylic acid, ascorbic acid, citric acid, succinic acid, butanedioic acid, pentanedioic acid, malic acid, tartaric acid, tannic acid, adipic acid, and derivatives thereof, and combinations thereof.

Item 14. The cleaning composition of item 1, wherein the at least one basic pH adjustor comprises one or more species selected from the group consisting of tetraethylammonium hydroxide (TEAH), tetramethylammonium hydroxide (TMAH), tetrapropylammonium hydroxide (TPAH), tetrabutylammonium hydroxide (TBAH), tributylmethylammonium hydroxide (TBMAH), benzyltrimethylammonium hydroxide (BTMAH), ethyltriethyl ammonium hydroxide (ETAH), methyl(trishydroxyethyl)ammonium hydroxide, tetrabutylphosphonium hydroxide (TBPH), ethyltrimethylammonium hydroxide (ETMAH), sodium hydroxide, potassium hydroxide, sodium carbonate, potassium carbonate, and derivatives thereof, and combinations thereof.

Item 15. The cleaning composition of item 1, wherein the at least one metal anticorrosive agent, wherein the metal anticorrosive agent comprises a species selected from the group consisting of benzotriazole (BTA), 1 H-1,2,4-triazole (TAZ), 5-nitrobenzotriazole, indazole, resorcin, pyruvate, adenine, adenosine, guanosine, glycine, iminodiacetic acid, ascorbic acid, ascorbic acid derivatives, citric acid, citric acid derivatives, uric acid, uric acid derivatives, and derivatives thereof, and combinations thereof.

Item 16. The cleaning composition of item 1, where the at least one metal anticorrosive agent comprises benzotriazole and ascorbic acid.

Item 17. The cleaning composition of item 16, wherein a relative amount of benzotriazole and the ascorbic acid is about 1:1.

Item 18. The cleaning composition of item 1, wherein the cleaning composition is free of TMAH (tetramethylammonium hydroxide), benzyltrimethylammonium hydroxide (BTMAH), or ethyltrimethylammonium hydroxide (ETMAH).

Item 19. The cleaning composition of item 1, wherein the at least one basic pH adjustor comprises one or more species selected from the group consisting of tetraethylammonium hydroxide (TEAH), tetrapropylammonium hydroxide (TPAH), tetrabutylammonium hydroxide (TBAH), tributylmethylammonium hydroxide (TBMAH), ethyltriethyl ammonium hydroxide (ETAH), methyl(trishydroxyethyl)ammonium hydroxide, tetrabutylphosphonium hydroxide (TBPH), sodium hydroxide, potassium hydroxide, sodium carbonate, potassium carbonate, and derivatives thereof, and combinations thereof.

Item 20. A method of removing contaminants from a microelectronic device, the method comprising cleaning a surface of the microelectronic device by contacting a surface to be cleaned with the cleaning composition according to item 1.

Item 21. The method of removing contaminants according to item 20, wherein the microelectronic device includes at least one of a copper (Cu) containing layer and a cobalt (Co) containing layer.

Item 22. The method of removing contaminants according to item 21, wherein the microelectronic device includes a copper/cobalt stack.

Item 23. The method of removing contaminants according to item 20, where the method follows a chemical mechanical planarization (CMP).

Item 24. The method of removing contaminants according to item 22, wherein a corrosion potential difference of copper and cobalt is less than about 220 mV.

Item 25. The method of removing contaminants according to item 20, wherein the composition is diluted with DI water in a ratio of about 1:20-100.

Item 26. A microelectronic device, the microelectronic device comprising:
a substrate;
a copper layer; and
a cobalt layer,
wherein contaminants on the surface of the copper layer and the cobalt layer on the surface of the substrate are removed in accordance with the method of item 20.

Item 27. The microelectronic device according to item 26, wherein the microelectronic device comprises a semiconductor substrates, flat panel displays, solar panels, photovoltaics, and microelectromechanical systems (MEMS).

Item 28. The microelectronic device according to item 26, wherein the copper layer and the cobalt layer is directly in contact with each other.

1. A cleaning composition for removing contaminants from a microelectronic device, the composition comprising:
at least one chelating agent;
at least one organic solvent;
at least one polycarboxylic acid;
at least one basic pH adjustor;
at least one metal anticorrosive agent; and
water.

2. The cleaning composition of claim 1, wherein the composition comprises:
at least one chelating agent in an amount ranging from 0 to about 5 wt.%;
at least one organic solvent in an amount ranging from about 0.1 to about 25 wt.%;
at least one polycarboxylic acid in an amount ranging from 0.01 to about 5 wt.%;
at least one basic pH adjustor in an amount ranging from about 1 to about 20 wt.%;
at least one metal anticorrosive agent in an amount ranging from about 0.01 to about 6 wt. %; and
water in an amount ranging from 39 to about 98 wt.%.

3. The cleaning composition of claim 1, wherein the composition comprises:
at least one chelating agent in an amount ranging from about 0.01 to about 3 wt. %;
at least one organic solvent in an amount ranging from about 0.5 to about 20 wt. %;
at least one polycarboxylic acid in an amount ranging from 0.01 to about 4 wt.%;
at least one basic pH adjustor in an amount ranging from about 1.5 to about 20 wt. %;
at least one metal anticorrosive agent in an amount ranging from about 0.01 to about 4 wt. %; and
water in an amount ranging from 49 to about 97 wt.%.

4. The cleaning composition of claim 1, wherein the composition comprises:
at least one chelating agent in an amount ranging from about 0.01 to about 2 wt. %;
at least one organic solvent in an amount ranging from about 2 to about 17 wt.%;
at least one polycarboxylic acid in an amount ranging from 0.01 to about 3 wt.%;
at least one basic pH adjustor in an amount ranging from about 2 to about 20 wt. %;
at least one metal anticorrosive agent in an amount ranging from about 0.01 to about 3 wt. %; and
water in an amount ranging from 55 to about 95 wt.%.

5. The cleaning composition of claim 1, wherein the composition comprises:
at least one chelating agent in an amount ranging from about 0.01 to about 1.5 wt. %;
at least one organic solvent in an amount ranging from about 3 to about 15 wt.%;
at least one polycarboxylic acid in an amount ranging from 0.01 to about 3 wt.%;
at least one basic pH adjustor in an amount ranging from about 4 to about 15 wt.%;
at least one metal anticorrosive agent in an amount ranging from about 0.01 to about 2.5 wt. %; and
water in an amount ranging from 63 to about 92 wt.%.

6. The cleaning composition of claim 1, wherein the composition comprises:
at least one chelating agent in an amount ranging from about 0.5 to about 1.5 wt. %;
at least one organic solvent in an amount ranging from about 7 to about 12 wt.%;
at least one polycarboxylic acid in an amount ranging from 0.01 to about 2.5 wt.%;
at least one basic pH adjustor in an amount ranging from about 7 to about 11 wt.%;
at least one metal anticorrosive agent in an amount ranging from about 0.5 to about 2.5 wt. %; and
water in an amount ranging from 70.5 to about 85 wt.%.

7. The cleaning composition of claim 1, wherein the composition has a pH in the range of 10 to 14.

8. The cleaning composition of claim 7, wherein the pH is in the range of 11 to 13.

9. The cleaning composition of claim 1, wherein the at least one chelating agent is selected from the group consisting of mono and/or polyalkylene polyamino polycarboxylic acids, polyaminoalkane polycarboxylic acids, and derivatives thereof, and combinations thereof.

10. The cleaning composition of claim 1, wherein the at least one chelating agent is selected from the group consisting of ethylenediaminetetraacetic acid diethylenetriaminepentaacetic acid, ethylenediaminetetra-n-propionic acid, triethylenetetramine hexaacetic acid, diaminopropanoltetraacetic acid, 1,3-propylenediaminetertaacetic acid, glycine, and iminodiacetic acid, and derivatives thereof, and combinations thereof.

11. The cleaning composition of claim 1, wherein the organic solvent is selected from the group consisting of water-soluble alcohol groups, ketone groups, ester groups, ether groups, and derivatives of the foregoing, and combinations of the foregoing.

12. The cleaning composition of claim 1, wherein the at least one polycarboxylic acid is selected from the group consisting of straight and/or branch chains, saturated and/or unsaturated, 2-20 carbon atom aromatic polycarboxylic acids, and derivatives of the foregoing, and combinations of the foregoing.

13. The cleaning composition of claim 1, wherein the polycarboxylic acid is selected from the group consisting of oxalic acid, malonic acid, tricarboxylic acid, ascorbic acid, citric acid, succinic acid, butanedioic acid, pentanedioic acid, malic acid, tartaric acid, tannic acid, adipic acid, and derivatives of the foregoing, and combinations of the foregoing .

14. The cleaning composition of claim 1, wherein the at least one basic pH adjustor is selected from the group consisting of tetraethylammonium hydroxide, tetramethylammonium hydroxide, tetrapropylammonium hydroxide, tetrabutylammonium hydroxide, tributylmethylammonium hydroxide, benzyltrimethylammonium hydroxide, ethyltriethyl ammonium hydroxide, methyl(trishydroxyethyl)ammonium hydroxide, tetrabutylphosphonium hydroxide, ethyltrimethylammonium hydroxide, sodium hydroxide, potassium hydroxide, sodium carbonate, potassium carbonate, and derivatives of the foregoing and combinations of the foregoing.

15. The cleaning composition of claim 1, wherein the at least one metal anticorrosive agent, wherein the metal anticorrosive agent is selected from the group consisting of benzotriazole, 1H-1 ,2,4-triazole, 5-nitrobenzotriazole, indazole, resorcin, pyruvate, adenine, adenosine, guanosine, glycine, iminodiacetic acid, ascorbic acid, ascorbic acid derivatives, citric acid, citric acid derivatives, uric acid, uric acid derivatives, and derivatives of the foregoing, and combinations of the foregoing.

16. The cleaning composition of claim 1, where the at least one metal anticorrosive agent comprises benzotriazole and ascorbic acid.

17. The cleaning composition of claim 16, wherein a relative amount of benzotriazole and the ascorbic acid is about 1:1 by weight percent.

18. The cleaning composition of claim 1, wherein the cleaning composition is free of tetramethylammonium hydroxide, benzyltrimethylammonium hydroxide, or ethyltrimethylammonium hydroxide.

19. The cleaning composition of claim 1, wherein the at least one basic pH adjustor comprises one or more species selected from the group consisting of tetraethylammonium hydroxide, tetrapropylammonium hydroxide, tetrabutylammonium hydroxide, tributylmethylammonium hydroxide, ethyltriethyl ammonium hydroxide, methyl(trishydroxyethyl)ammonium hydroxide, tetrabutylphosphonium hydroxide, sodium hydroxide, potassium hydroxide, sodium carbonate, potassium carbonate, and derivatives thereof, and combinations thereof.

20. A method of removing contaminants from a microelectronic device, the method comprising cleaning a surface of the microelectronic device by contacting a surface to be cleaned with the cleaning composition according to claim 1.

21-23. (canceled)
